(19) United States
(12) Patent Application Publication
(10) Pub. No.: US 2015/0200013 A1
(43) Pub. Date: Jul. 16, 2015

(54) NON-VOLATILE MEMORY AND MEMORY CELL THEREOF

(71) Applicant: Chrong-Jung Lin, Hsinchu City (TW)

(72) Inventor: Chrong-Jung Lin, Hsinchu City (TW)

(21) Appl. No.: 14/504,572

(22) Filed: Oct. 2, 2014

(30) Foreign Application Priority Data
Jan. 15, 2014 (TW) 103101395

(51) Int. Cl. G11C 16/10; G11C 13/00

(52) U.S. Cl. CPC G11C 16/10; G11C 13/0069

(57) ABSTRACT

A memory cell of a non-volatile memory includes a storage transistor and a resistive element. The storage transistor includes a gate structure, a first doped region and a second doped region. A first end of the resistive element is connected to the second doped region. The storage transistor is programmed to be at least in a first storing status or a second storing status. The resistive element is programmed to be at least in the first storing status or the second storing status. A control terminal of the memory cell is connected to the gate structure. A first terminal of the memory cell is connected to the first doped region. A second terminal of the memory cell is connected to a second end of the resistive element.

This application claims the benefit of Taiwan Patent Application No. 103101395, filed Jan. 15, 2014, the subject matter of which is incorporated herein by reference.

### FIELD OF THE INVENTION

The present invention relates to a memory and a memory cell thereof, and more particularly to a non-volatile memory and a memory cell thereof.

### BACKGROUND OF THE INVENTION

As is well known, a non-volatile memory is able to continuously retain data after the supplied power is interrupted. A flash memory is one of the most popular non-volatile memories. Generally, each memory cell of the flash memory has a floating gate transistor as a storage element. The storing status of the floating gate transistor may be determined according to the amount of the stored charges.

FIG. 1 is a schematic cross-sectional view illustrating a floating gate transistor of a conventional non-volatile memory. As shown in FIG. 1, the floating gate transistor 10 comprises two stacked and separated gates. The upper gate is a control gate 12, which is connected to a control line C. The lower gate is a floating gate 14. In addition, an n-type doped source region and an n-type doped drain region are constructed in a P-substrate. The n-type doped source region is connected to a source line S. The n-type doped drain region is connected to a drain line D.

For example, during a program cycle, a high voltage (e.g. +16V) is provided by the drain line D, a ground voltage is provided by the source line S, and a control voltage (e.g. +25V) is provided by the control line C. Consequently, while the electrons are transmitted from the source line S to the drain line D through an n-channel region, the hot carriers (e.g. hot electrons) are attracted by the control voltage at the control gate 12 and injected into the floating gate 14. Under this circumstance, a great number of carriers are accumulated in the floating gate 14. Consequently, the programmed state may be considered as a first storing status (e.g. “0”). In case that the non-volatile memory is in a non-programmed state, no carrier is injected into the floating gate 14, and thus the non-programmed state may be considered as a second storing status (e.g. “1”).

In other words, the threshold voltages of the floating gate transistor 10 in the first storing status and the second storing status are subject to changes. Consequently, the characteristics of the drain current (id) and the gate-source voltage (Vgs) (i.e. the id-Vgs characteristics) in the first storing status and the id-Vgs characteristics in the second storing status are distinguished. Consequently, during a read cycle, the storing status of the floating gate transistor 10 may be realized according to the variation of the id-Vgs characteristics.

FIG. 2A is a schematic circuit diagram of a conventional NOR flash memory. As shown in FIG. 2A, the NOR flash memory comprises plural cells Cnor0˜Cnor7. The plural cells Cnor0˜Cnor7 comprises respective floating gate transistors M0˜M7 as storage elements. Each of these floating gate transistors M0˜M7 stores one bit of data.

The control terminals of the floating gate transistors M7˜M0 are connected to corresponding word lines WL7˜WL0, respectively. Moreover, the first terminals (e.g. the drain terminals) of the floating gate transistors M7˜M0 are connected with the bit line BL. Moreover, the second terminals (e.g. the source terminals) of the floating gate transistors M7˜M0 are connected with a ground terminal GND.

Moreover, by providing proper bias voltages to the bit line BL and the word lines WL0˜WL7, the NOR flash memory may be programmed, read or erased.

FIG. 2B is a schematic circuit diagram of a conventional NAND flash memory. As shown in FIG. 2B, the NAND flash memory comprises a select transistor Msel and plural cells Cnand0˜Cnand7. The plural cells Cnand0˜Cnand7 comprises respective floating gate transistors M0˜M7 as storage elements. Each of these floating gate transistors M0˜M7 stores one bit of data.

The control terminal of the select transistor Msel is connected to a select line SEL. The first terminal (e.g. the drain terminal) of the select transistor Msel is connected to the bit line BL. Moreover, the floating gate transistors M7˜M0 are connected between the second terminal (e.g. the source terminal) of the select transistor Msel and a ground terminal GND in series. The control terminals of the floating gate transistors M7˜M0 are connected to corresponding word lines WL7˜WL0, respectively.

Similarly, by providing proper bias voltages to the bit line BL, the word lines WL0˜WL7 and the select line SEL, the NAND flash memory may be programmed, read or erased.

As mentioned above, the memory cell of the conventional flash memory comprises one floating gate transistor for storing one bit of data.

Recently, a non-volatile memory with a resistive element as the main storage element has been introduced into the market. This non-volatile memory is also referred as a resistive random access memory (RRAM). In the resistive random access memory, each memory cell comprises a resistive element as a storage element. Each resistive element stores one bit of data.

FIGS. 3A and 3B are schematic cross-sectional views illustrating two conventional resistive elements. The two resistive elements are disclosed in U.S. Pat. No. 8,107,274 for example.

As shown in FIG. 3A, the resistive element 160 comprises a transition metal oxide layer 110, a bottom electrode 120, a conductive plug module 130, and a dielectric layer 150. The conductive plug module 130 comprises a metal plug 132 and a barrier layer 134. The metal plug 132 is vertically disposed over the transition metal oxide layer 110, and electrically connected with the transition metal oxide layer 110. The barrier layer 134 is arranged around the metal plug 132.

Moreover, two sections 140 and 142 of the transition metal oxide layer 110 are formed by a reaction between a portion of the barrier layer 134 and a portion of the dielectric layer 150. As shown in FIG. 3A, after the transition metal oxide layer 110 is formed, a part of the dielectric layer 150 is still arranged between the transition metal oxide layer 110 and the bottom electrode 120. Although the part of the dielectric layer 150 is arranged between the transition metal oxide layer 110 and the bottom electrode 120, the electrical connection between the conductive plug module 130 and the bottom electrode 120 is achieved through the transition metal oxide layer 110 and the dielectric layer 150.

As shown in FIG. 3B, the resistive element 170 comprises a transition metal oxide layer 110, a bottom electrode 120, a conductive plug module 130, and a dielectric layer 150. Similarly, the transition metal oxide layer 110 is formed by a reaction between a portion of the barrier layer 134 and a portion of the dielectric layer 150. However, in comparison with FIG. 3A, the transition metal oxide layer 110 of the resistive element 170 is in direct contact with the bottom electrode 120. Consequently, the electrical connection between the conductive plug module 130 and the bottom electrode 120 is achieved through the transition metal oxide layer 110.

Moreover, for providing different resistance values, the transition metal oxide layer 110 may be selectively set or reset. Consequently, the resistive elements 160 and 170 are variable and reversible resistive elements. In other words, the resistive elements 160 and 170 may be used as storage elements. Generally, the action of setting the resistive element 160 or 170 is equivalent to a program action, and the action of resetting the resistive element 160 or 170 is equivalent to an erase action.

FIG. 4 is a plot illustrating the resistive characteristics of the transition metal oxide layer of the resistive element. For setting the transition metal oxide layer 110, a set voltage (e.g. about 3V) is provided to the transition metal oxide layer 110, so that the transition metal oxide layer 110 is in a first storing status and has a low resistance value. For resetting the transition metal oxide layer 110, a reset voltage (e.g. about 1V) and a rest current (e.g. 100 μA) are provided to the transition metal oxide layer 110, so that the transition metal oxide layer 110 is in a second storing status and has a high resistance value.

Moreover, during a read cycle, only a small read voltage (e.g. about 0.4V˜1V) is provided to the transition metal oxide layer 110. According to the magnitude of the corresponding read current, the storing status of the transition metal oxide layer 110 can be realized. For example, if the read current generated by the transition metal oxide layer 110 is lower than 5 μA during the read cycle, the transition metal oxide layer 110 is in the second storing status (i.e. with a high resistance value). Whereas, if the read current generated by the transition metal oxide layer 110 is higher than 5 μA during the read cycle, the transition metal oxide layer 110 is in the first storing status (i.e. with a low resistance value).

### SUMMARY OF THE INVENTION

The present invention provides a non-volatile memory and a memory cell thereof. The memory cell of the non-volatile memory comprises a resistive element and a storage transistor, and is capable of storing plural bits of data.

An embodiment of the present invention provides a memory cell of a non-volatile memory. The memory cell includes a storage transistor and a resistive element. The storage transistor includes a gate structure, a first doped region and a second doped region. A first end of the resistive element is connected to the second doped region. The storage transistor is programmed to be at least in a first storing status or a second storing status. The resistive element is programmed to be at least in the first storing status or the second storing status. A control terminal of the memory cell is connected to the gate structure. A first terminal of the memory cell is connected to the first doped region. A second terminal of the memory cell is connected to a second end of the resistive element.

Another embodiment of the present invention provides a non-volatile memory. The non-volatile memory includes a bit line, a first word line and a first memory cell. A control terminal of the first memory cell is connected to the first word line. A first terminal of the first memory cell is connected to the bit line. A second terminal of the first memory cell is connected to a ground terminal. The first memory cell includes a first storage transistor and a first resistive element. The first storage transistor includes a first gate structure, a first doped region and a second doped region. A first end of the first resistive element is connected to the second doped region. The first storage transistor is programmed to be at least in a first storing status or a second storing status. The first resistive element is programmed to be at least in the first storing status or the second storing status. The control terminal of the first memory cell is connected to the first gate structure. At least one of the first doped region and a second end of the first resistive element is connected to the first terminal of the first memory cell. The other one of the first doped region and the second end of the first resistive element is connected to the second terminal of the first memory cell.

A further embodiment of the present invention provides a bit line, M word lines, a select line, a select transistor and M memory cells, wherein M is a positive integer larger than 1. A select terminal of the select transistor is connected to the select line. A first terminal of the select transistor is connected to the bit line. The M memory cells are connected between a second terminal of the select transistor and a ground terminal. Each of the memory cells has a control terminal connected to a corresponding word line of the M word lines. A first memory cell of the M memory cells includes a storage transistor and a resistive element. The storage transistor includes a gate structure, a first doped region and a second doped region. A first end of the resistive element is connected to the second doped region. The storage transistor is programmed to be at least in a first storing status or a second storing status. The resistive element is programmed to be at least in the first storing status or the second storing status. The control terminal of the first memory cell is connected to the gate structure. The first doped region is connected to a first terminal of the first memory cell. A second end of the resistive element is connected to a second terminal of the first memory cell.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic cross-sectional view illustrating a floating gate transistor of a conventional non-volatile memory;

FIG. 2A (prior art) is a schematic circuit diagram of a conventional NOR flash memory;

FIG. 2B (prior art) is a schematic circuit diagram of a conventional NAND flash memory;

FIGS. 3A and 3B (prior art) are schematic cross-sectional views illustrating two conventional resistive elements;

FIG. 4 is (prior art) a plot illustrating the resistive characteristics of the transition metal oxide layer of the resistive element;

FIG. 5A is a schematic cross-sectional view illustrating a memory cell of a non-volatile memory according to a first embodiment of the present invention;

FIG. 5B is a schematic cross-sectional view illustrating a memory cell of a non-volatile memory according to a second embodiment of the present invention;

FIG. 5C schematically illustrates an equivalent circuit of the non-volatile memory of the present invention;

FIG. 6A is a schematic circuit diagram illustrating a non-volatile memory comprising plural memory cells according to an embodiment of the present invention;

FIG. 6B is a schematic circuit diagram illustrating a non-volatile memory comprising plural memory cells according to another embodiment of the present invention;

FIG. 7 is a schematic circuit diagram illustrating a non-volatile memory comprising plural memory cells according to a further embodiment of the present invention;

FIG. 8A is a schematic cross-sectional view illustrating a memory cell of a non-volatile memory according to a third embodiment of the present invention; and

FIG. 8B is a schematic cross-sectional view illustrating a memory cell of a non-volatile memory according to a fourth embodiment of the present invention.

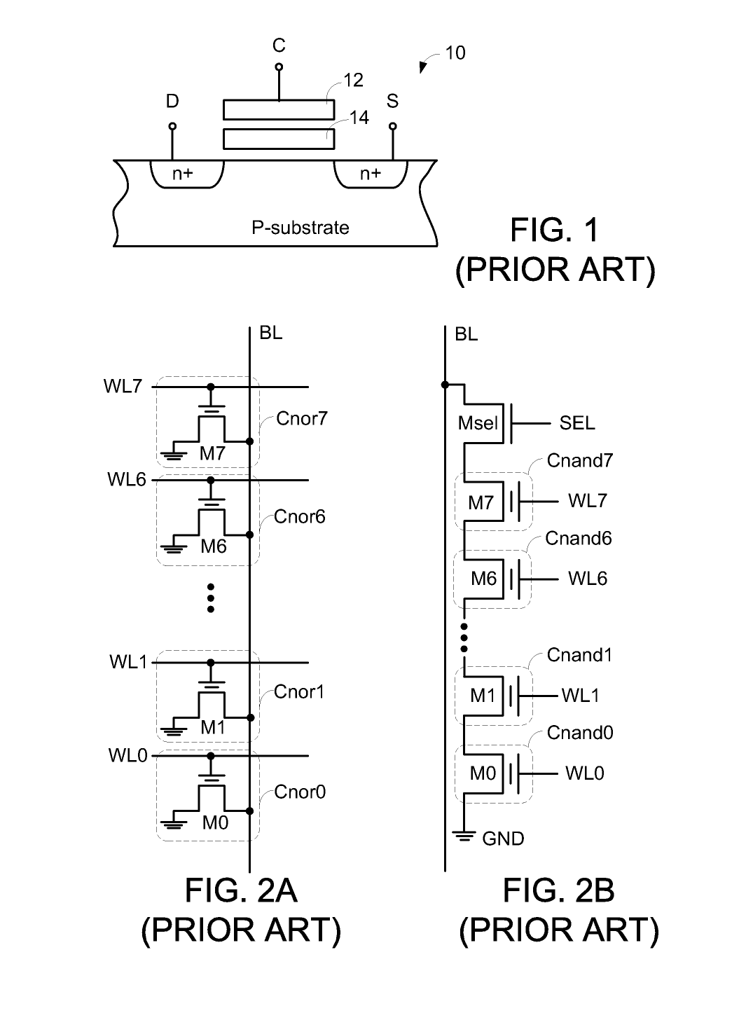

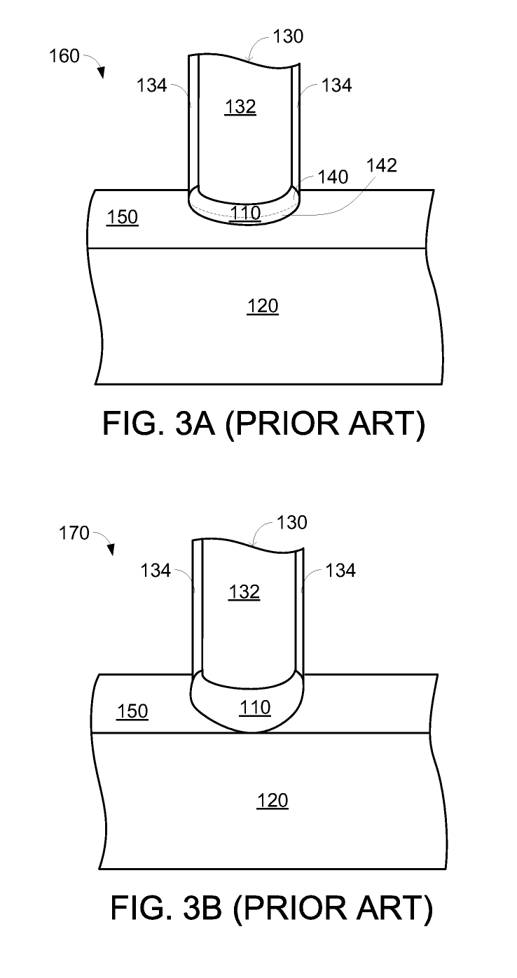

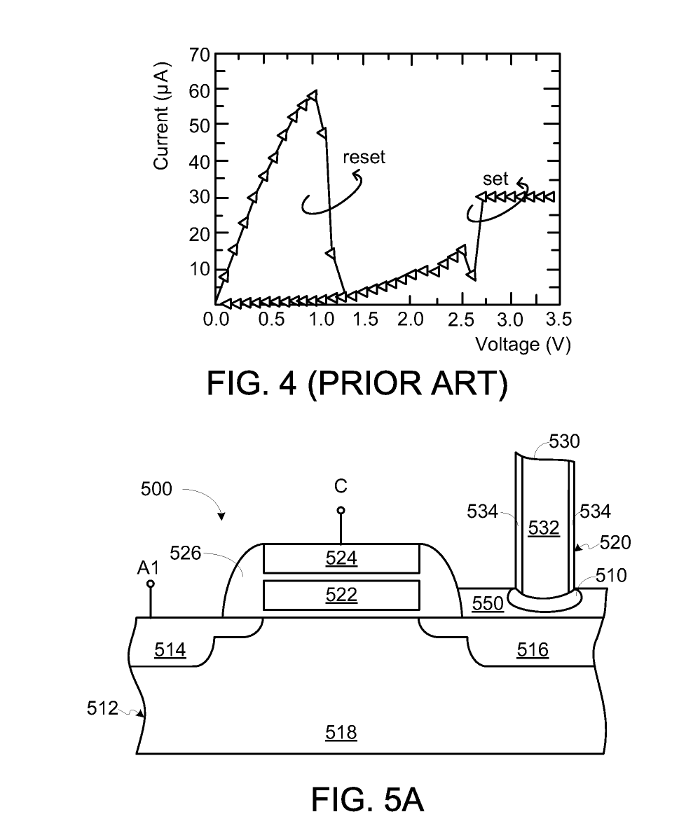

### DETAILED DESCRIPTION OF PREFERRED EMBODIMENTS

The present invention provides a novel non-volatile memory and a memory cell thereof. The memory cell of the non-volatile memory comprises a resistive element and a storage transistor, and is capable of storing plural bits of data. The concepts of the present invention will be illustrated in more details.

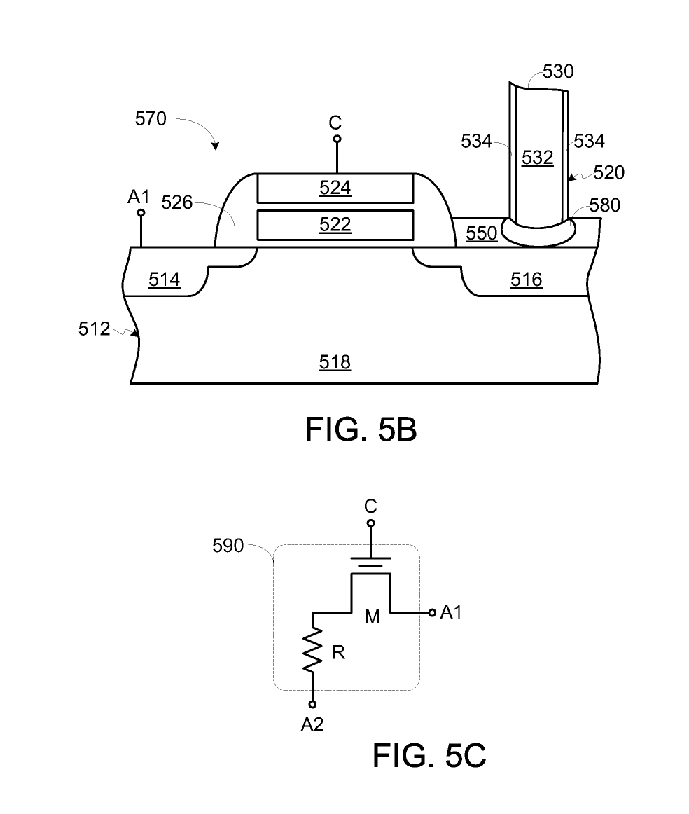

FIG. 5A is a schematic cross-sectional view illustrating a memory cell of a non-volatile memory according to a first embodiment of the present invention. As shown in FIG. 5A, the memory cell 500 comprises a floating gate transistor 512 and a resistive element 520. The floating gate transistor 512 is a storage transistor. The floating gate transistor 512 comprises two stacked and separated gates. The upper gate is a control gate 524, which is connected to a control terminal C. The lower gate is a floating gate 522. Moreover, a spacer 526 is arranged around the control gate 524 and the floating gate 522. In addition, a first doped region 514 and a second doped region 516 are constructed in a substrate 518. The first doped region 514 is connected to a first terminal A1.

The resistive element 520 is electrically connected with the second doped region 516. In this embodiment, the resistive element 520 is a variable and reversible resistive element. The resistive element 520 comprises a transition layer 510, a dielectric layer 550, and a conductive plug module 530. The dielectric layer 550 is formed on the second doped region 516. The conductive plug module 530 is formed over the transition layer 510. The conductive plug module 530 comprises a metal plug 532 and a barrier layer 534. The metal plug 532 is vertically disposed over the transition layer 510, and electrically connected with the transition layer 510. The barrier layer 534 is arranged around the metal plug 532.

The transition layer 510 is formed by a reaction between the dielectric layer 550 and the barrier layer 534. Moreover, the resistance value of the transition layer 510 is adjustable. Although a part of the dielectric layer 550 is arranged between the transition layer 510 and the second doped region 516, the electrical connection between the conductive plug module 530 and the second doped region 516 is achieved through the transition layer 510 and the dielectric layer 550.

In an embodiment, the dielectric layer 550 is made of silicon dioxide (SiO₂). The metal plug 532 is made of copper, aluminum or tungsten. The barrier layer 534 is made of Hf, HfOx, HfOxNy, Mg, MgOx, MgOxNy, NiOx, NiOxNy, TaOxNy, Ta, TaOx, TaNx, TiOxNy, Ti, TiOx or TiNx. Moreover, the transition layer 510 is made of HfOx, HfOxNy, MgOx, MgOxNy, NiOx, NiOxNy, TaOxNy, TaOx, TaNx, TiOxNy, TiOx or TiNx. Among these materials, HfOx, MgOx, NiOx, TaOx and TiOx are transition metal oxides, TaNx and TiNx are transition metal nitrides, and HfOxNy, MgOxNy, NiOxNy, TaOxNy and TiOxNy are transition metal nitrogen oxide dielectric materials.

FIG. 5B is a schematic cross-sectional view illustrating a memory cell of a non-volatile memory according to a second embodiment of the present invention. Similarly, the transition layer 580 is formed by a reaction between the dielectric layer 550 and the barrier layer 534. However, in comparison with the first embodiment, the transition metal oxide layer 580 of this embodiment is in direct contact with the second doped region 516. Consequently, the electrical connection between the conductive plug module 530 and the second doped region 516 is achieved through the transition metal oxide layer 580.

FIG. 5C schematically illustrates an equivalent circuit of the non-volatile memory of the present invention. As shown in FIG. 5C, the memory cell 590 comprises a resistive element R and a floating gate transistor M. A first end of the resistive element R is connected to the second doped region of the floating gate transistor M.

Moreover, a control terminal of the memory cell 590 is connected to a control gate of the floating gate transistor M. A first terminal A1 of the memory cell 590 is connected to the first doped region 514 of the floating gate transistor M. A second terminal A2 of the memory cell 590 is connected to a second end of the resistive element R.

In accordance with the present invention, both of the resistive element R and the floating gate transistor M can be used as storage elements. Consequently, the memory cell 590 can store at least two bits of data. That is, by providing proper bias voltages to the memory cell 590, the floating gate transistor M is selectively in a first storing status or a second storing status and the resistive element R is selectively in the first storing status or the second storing status.

From the above descriptions, the memory cell 590 may have four storing statuses. Moreover, during the read cycle, four different read currents corresponding to the four storing statuses are generated. According to the magnitude of the read current, the storing status of the memory cell 590 is determined.

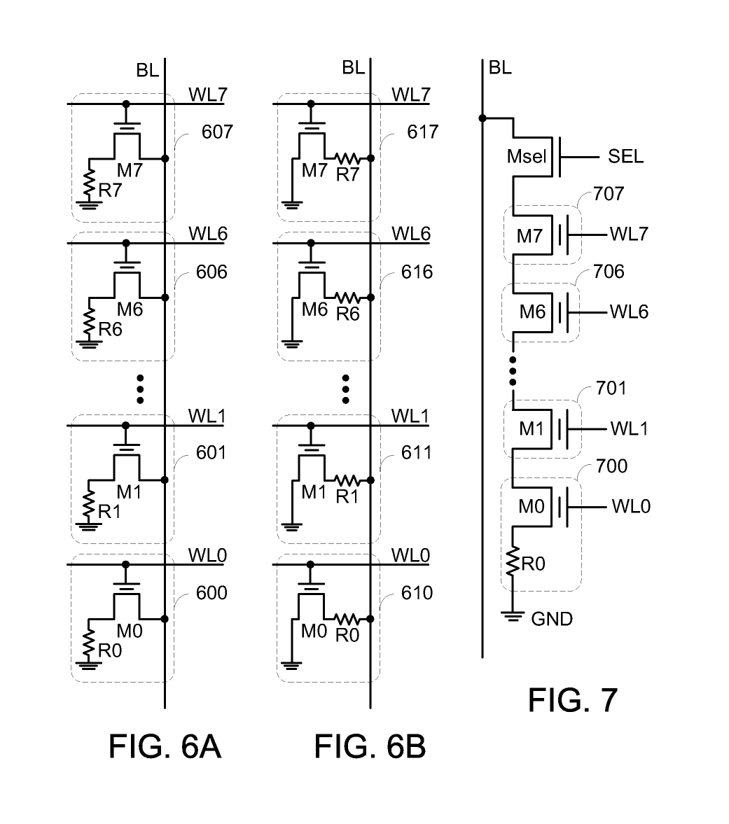

FIG. 6A is a schematic circuit diagram illustrating a non-volatile memory comprising plural memory cells according to an embodiment of the present invention. As shown in FIG. 6A, the non-volatile memory comprises plural memory cells 600˜607. Each of the plural memory cells 600˜607 comprises a storage transistor and a resistive element. For example, in the seventh memory cell 607, both of the storage transistor M7 and the resistive element R7 are storage elements for storing two bits of data. The control terminals of the memory cells 600˜607 are connected to the corresponding word lines WL0˜WL7, respectively. The first terminals of the memory cells 600˜607 are connected to a bit line BL. The second terminals of the memory cells 600˜607 are connected to a ground terminal GND. In this embodiment, the storage elements are floating gate transistors.

Similarly, by providing proper bias voltages to the bit line BL and the word lines WL0˜WL7, the storage transistor or the resistive element of each memory cell may be programmed or erased. Moreover, during the read cycle, the storing status of each of the memory cells 600˜607 can be realized.

It is noted that numerous modifications may be made while retaining the teachings of the invention. FIG. 6B is a schematic circuit diagram illustrating a non-volatile memory comprising plural memory cells according to another embodiment of the present invention. As shown in FIG. 6B, the non-volatile memory comprises plural memory cells 610˜617. Each of the plural memory cells 610˜617 comprises a storage transistor and a resistive element. The control terminals of the memory cells 610˜617 are connected to the corresponding word lines WL0˜WL7, respectively. The first terminals of the memory cells 610˜617 are connected to a ground terminal GND. The second terminals of the memory cells 610˜617 are connected to a bit line BL.

Similarly, by providing proper bias voltages to the bit line BL and the word lines WL0˜WL7, the storage transistor or the resistive element of each memory cell may be programmed or erased. Moreover, during the read cycle, the storing status of each of the memory cells 610˜617 can be realized.

FIG. 7 is a schematic circuit diagram illustrating a non-volatile memory comprising plural memory cells according to a further embodiment of the present invention. As shown in FIG. 7A, the non-volatile memory comprises a select transistor Msel and plural memory cells 700˜707. The plural memory cells 700˜707 comprises respective storage transistors M0˜M7 as storage elements. Each of these storage transistors M0˜M7 stores one bit of data. Moreover, one of the plural memory cells 700˜707 further comprises a resistive element. For example, as shown in FIG. 7, the memory cell 700 comprises a storage transistor M0 and a resistive element R0.

The control terminal of the select transistor Msel is connected to a select line SEL. The first terminal (e.g. the drain terminal) of the select transistor Msel is connected to the bit line BL. Moreover, the plural memory cells 700˜707 are connected between the second terminal (e.g. the source terminal) of the select transistor Msel and a ground terminal GND in series. The control terminals of the storage transistors M7˜M0 are connected to corresponding word lines WL7˜WL0, respectively.

Similarly, by providing proper bias voltages to the bit line B, the word lines WL0˜WL7 and the select transistor Msel, the storage transistor or the resistive element of each memory cell may be programmed or erased.

In this embodiment, the resistance value of the resistive element R0 of the memory cell 700 may be determined by setting or resetting the resistive element R0. Consequently, the program current, the erase current and the read current can be accurately trimmed.

It is noted that the storage transistor is not restricted to the floating gate transistor. It is noted that any other appropriate transistor may be used as the storage transistor while achieving the similar efficacy.

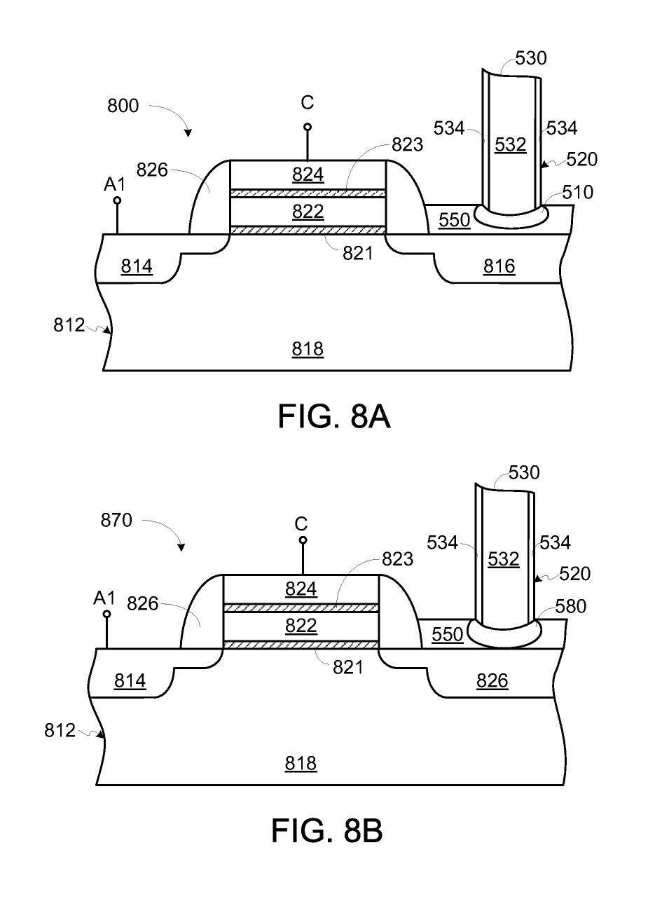

For example, in some other embodiments, the storage transistor is a silicon-oxide-nitride-oxide-silicon (SONOS) transistor. FIG. 8A is a schematic cross-sectional view illustrating a memory cell of a non-volatile memory according to a third embodiment of the present invention. FIG. 8B is a schematic cross-sectional view illustrating a memory cell of a non-volatile memory according to a fourth embodiment of the present invention. The structures of the resistive elements 520 of the memory cell 800 of FIG. 8A and the memory cell 870 of FIG. 8B are similar to the resistive elements of the first embodiment and the second embodiment, and are not redundantly described herein.

In comparison with the floating gate transistor, the gate structure of the SONOS transistor is distinguished. As mentioned above, the gate structure of the floating gate transistor comprises a floating gate and a control gate. The floating gate is disposed over the surface of the substrate 818 between the first doped region and the second doped region. The control gate is disposed over the floating gate and connected to the control terminal. On the other hand, the gate structure of the SONOS transistor 812 comprises a first oxide layer 821, a nitride layer 822, a second oxide layer 823, and a gate electrode 824. For example, the first oxide layer 821 and the second oxide layer 823 are made of silicon dioxide (SiO₂), the nitride layer 822 is made of silicon dioxide (Si₃N₄), and the gate electrode 824 is made of polysilicon. In other words, the materials of the gate structure from the gate electrode 824 to the substrate 818 are sequentially the semiconductor material, the oxide material, the nitride material, the oxide material and the semiconductor material. Consequently, this storage transistor is referred as the SONOS transistor.

In the above two embodiments, the SONOS transistor 812 comprises the substrate 818, the gate structure and a spacer 826. A first doped region 814 and a second doped region 816 are constructed in a substrate 818. The gate structure is disposed over the surface of the substrate 818 between the first doped region 814 and the second doped region 816. The gate structure comprises the first oxide layer 821, the nitride layer 822, the second oxide layer 823 and the gate electrode 824, which are sequentially arranged in a stack form. The control terminal C is connected to the gate electrode 824. The spacer 826 is disposed over the surface of the substrate 818 and arranged around the gate structure.

In the above embodiments, one storage transistor stores one bit data. It is noted that some special types of storage transistors may store plural bits of data. In case that the memory cell comprises the special storage transistor and the resistive element, the memory cell may store the data with more than two bits. For example, in case that the memory cell comprises a storage transistor storing two bits and a resistive element storing one bit, the memory cell may store three bits of data. Under this circumstance, the memory cell has eight storing statuses.

Moreover, by precisely controlling the resistance value of the resistive element, the resistive element can store more bits. The memory cell with this resistive element and the storage transistor can store the data with more than three bits. Under this circumstance, the memory cell has more storing statuses.

From the above descriptions, the present invention provides a novel non-volatile memory and a memory cell thereof. Each memory cell can store plural bits of data. The memory cell comprises a resistive element and a storage transistor. Moreover, by means of the memory cell, the program current, the erase current and the read current of the non-volatile memory can be effectively trimmed.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A memory cell of a non-volatile memory, the memory cell comprising:
a storage transistor comprising a gate structure, a first doped region and a second doped region; and
a resistive element having a first end connected to the second doped region;
wherein the storage transistor is programmed to be at least in a first storing status or a second storing status, and the resistive element is programmed to be at least in the first storing status or the second storing status, wherein a control terminal of the memory cell is connected to the gate structure, a first terminal of the memory cell is connected to the first doped region, and a second terminal of the memory cell is connected to a second end of the resistive element.

2. The memory cell as claimed in claim 1, wherein the storage transistor is a floating gate transistor, and the storage transistor comprises:
a substrate, wherein the first doped region and the second doped region are formed in the substrate;
the gate structure comprising a floating gate and a control gate, wherein the floating gate is disposed over a surface of the substrate between the first doped region and the second doped region, and the control gate is disposed over the floating gate and connected to the control terminal; and
a spacer disposed over the surface of the substrate and arranged around the gate structure.

3. The memory cell as claimed in claim 1, wherein the storage transistor is a silicon-oxide-nitride-oxide-silicon transistor, and the storage transistor comprises:
a substrate, wherein the first doped region and the second doped region are formed in the substrate;
the gate structure disposed over a surface of the substrate between the first doped region and the second doped region, wherein the gate structure comprises a first oxide layer, a nitride layer, a second oxide layer and a gate electrode, which are sequentially arranged in a stack form, wherein the gate electrode is connected to the control terminal; and
a spacer disposed over the surface of the substrate and arranged around the gate structure.

4. The memory cell as claimed in claim 1, wherein the resistive element comprises:
a dielectric layer formed on and contacted with the second doped region;
a transition layer formed over the second doped region; and
a conductive plug module formed on and contacted with the transition layer,
wherein the conductive plug module comprises a metal plug and a barrier layer, wherein the metal plug is disposed over the transition layer, and the barrier layer is arranged around the metal plug.

5. The memory cell as claimed in claim 4, wherein the metal plug is made of copper, aluminum or tungsten.

6. The memory cell as claimed in claim 4, wherein the dielectric layer is made of silicon dioxide.

7. The memory cell as claimed in claim 6, wherein the barrier layer is made of Hf, HfOx, HfOxNy, Mg, MgOx, MgOxNy, NiOx, NiOxNy, TaOxNy, Ta, TaOx, TaNx, TiOxNy, Ti, TiOx or TiNx.

8. The memory cell as claimed in claim 7, wherein the transition layer is made of HfOx, HfOxNy, MgOx, MgOxNy, NiOx, NiOxNy, TaOxNy, TaOx, TaNx, TiOxNy, TiOx or TiNx.

9. A non-volatile memory, comprising:
a bit line;
a first word line; and
a first memory cell, wherein a control terminal of the first memory cell is connected to the first word line, a first terminal of the first memory cell is connected to the bit line, and a second terminal of the first memory cell is connected to a ground terminal, wherein the first memory cell comprises a first storage transistor and a first resistive element, wherein the first storage transistor comprises a first gate structure, a first doped region and a second doped region, and a first end of the first resistive element is connected to the second doped region, wherein the first storage transistor is programmed to be at least in a first storing status or a second storing status, and the first resistive element is programmed to be at least in the first storing status or the second storing status,
wherein the control terminal of the first memory cell is connected to the first gate structure, at least one of the first doped region and a second end of the first resistive element is connected to the first terminal of the first memory cell, and the other one of the first doped region and the second end of the first resistive element is connected to the second terminal of the first memory cell.

10. The non-volatile memory as claimed in claim 9, further comprising:
a second word line; and
a second memory cell, wherein a control terminal of the second memory cell is connected to the second word line, a first terminal of the second memory cell is connected to the bit line, and a second terminal of the second memory cell is connected to the ground terminal, wherein the second memory cell comprises a second storage transistor and a second resistive element, wherein the second storage transistor comprises a second gate structure, a third doped region and a fourth doped region, and a first end of the second resistive element is connected to the fourth doped region, wherein the second storage transistor is programmed to be at least in the first storing status or the second storing status, and the second resistive element is programmed to be at least in the first storing status or the second storing status,
wherein the control terminal of the second memory cell is connected to the second gate structure, at least one of the third doped region and a second end of the second resistive element is connected to the first terminal of the second memory cell, and the other one of the third doped region and the second end of the second resistive element is connected to the second terminal of the second memory cell.

11. The non-volatile memory as claimed in claim 9, wherein the first storage transistor is a floating gate transistor, and the first storage transistor comprises:
a substrate, wherein the first doped region and the second doped region are formed in the substrate;
the first gate structure comprising a floating gate and a control gate, wherein the floating gate is disposed over a surface of the substrate between the first doped region and the second doped region, and the control gate is disposed over the floating gate and connected to the control terminal; and
a spacer disposed over the surface of the substrate and arranged around the first gate structure.

12. The non-volatile memory as claimed in claim 9, wherein the first storage transistor is a silicon-oxide-nitride-oxide-silicon transistor, and the first storage transistor comprises:
a substrate, wherein the first doped region and the second doped region are formed in the substrate;
the first gate structure disposed over a surface of the substrate between the first doped region and the second doped region, wherein the first gate structure comprises a first oxide layer, a nitride layer, a second oxide layer and a gate electrode, which are sequentially arranged in a stack form, wherein the gate electrode is connected to the control terminal; and
a spacer disposed over the surface of the substrate and arranged around the first gate structure.

13. The non-volatile memory as claimed in claim 9, wherein the first resistive element comprises:
a dielectric layer formed on and contacted with the second doped region;
a transition layer formed over the second doped region; and
a conductive plug module formed on and contacted with the transition layer,
wherein the conductive plug module comprises a metal plug and a barrier layer, wherein the metal plug is disposed over the transition layer, and the barrier layer is arranged around the metal plug.

14. The non-volatile memory as claimed in claim 13, wherein the metal plug is made of copper, aluminum or tungsten.

15. The non-volatile memory as claimed in claim 13, wherein the dielectric layer is made of silicon dioxide.

16. The non-volatile memory as claimed in claim 15, wherein the barrier layer is made of Hf, HfOx, HfOxNy, Mg, MgOx, MgOxNy, NiOx, NiOxNy, TaOxNy, Ta, TaOx, TaNx, TiOxNy, Ti, TiOx or TiNx.

17. The non-volatile memory as claimed in claim 16, wherein the transition layer is made of HfOx, HfOxNy, MgOx, MgOxNy, NiOx, NiOxNy, TaOxNy, TaOx, TaNx, TiOxNy, TiOx or TiNx.

18. A non-volatile memory, comprising:
a bit line;
M word lines, wherein M is a positive integer larger than 1;
a select line;
a select transistor, wherein a select terminal of the select transistor is connected to the select line, and a first terminal of the select transistor is connected to the bit line; and
M memory cells connected between a second terminal of the select transistor and a ground terminal in series, wherein each of the memory cells has a control terminal connected to a corresponding word line of the M word lines, wherein a first memory cell of the M memory cells comprises a storage transistor and a resistive element, wherein the storage transistor comprises a gate structure, a first doped region and a second doped region, and a first end of the resistive element is connected to the second doped region, wherein the storage transistor is programmed to be at least in a first storing status or a second storing status, and the resistive element is programmed to be at least in the first storing status or the second storing status,
wherein the control terminal of the first memory cell is connected to the gate structure, the first doped region is connected to a first terminal of the first memory cell, and a second end of the resistive element is connected to a second terminal of the first memory cell.

19. The non-volatile memory as claimed in claim 18, wherein the storage transistor is a floating gate transistor, and the storage transistor comprises:
a substrate, wherein the first doped region and the second doped region are formed in the substrate;
the gate structure comprising a floating gate and a control gate, wherein the floating gate is disposed over a surface of the substrate between the first doped region and the second doped region, and the control gate is disposed over the floating gate and connected to the control terminal; and
a spacer disposed over the surface of the substrate and arranged around the gate structure.

20. The non-volatile memory as claimed in claim 18, wherein the storage transistor is a silicon-oxide-nitride-oxide-silicon transistor, and the storage transistor comprises:
a substrate, wherein the first doped region and the second doped region are formed in the substrate;
the gate structure disposed over a surface of the substrate between the first doped region and the second doped region, wherein the gate structure comprises a first oxide layer, a nitride layer, a second oxide layer and a gate electrode, which are sequentially arranged in a stack form, wherein the gate electrode is connected to the control terminal; and
a spacer disposed over the surface of the substrate and arranged around the gate structure.

21. The non-volatile memory as claimed in claim 18, wherein the resistive element comprises:
a dielectric layer formed on and contacted with the second doped region;
a transition layer formed over the second doped region; and
a conductive plug module formed on and contacted with the transition layer,
wherein the conductive plug module comprises a metal plug and a barrier layer, wherein the metal plug is disposed over the transition layer, and the barrier layer is arranged around the metal plug.

22. The non-volatile memory as claimed in claim 21, wherein the metal plug is made of copper, aluminum or tungsten.

23. The non-volatile memory as claimed in claim 21, wherein the dielectric layer is made of silicon dioxide.

24. The non-volatile memory as claimed in claim 23, wherein the barrier layer is made of Hf, HfOx, HfOxNy, Mg, MgOx, MgOxNy, NiOx, NiOxNy, TaOxNy, Ta, TaOx, TaNx, TiOxNy, Ti, TiOx or TiNx.

25. The non-volatile memory as claimed in claim 24, wherein the transition layer is made of HfOx, HfOxNy, MgOx, MgOxNy, NiOx, NiOxNy, TaOxNy, TaOx, TaNx, TiOxNy, TiOx or TiNx.
